(19) United States
(12) Patent Application Publication
(10) Pub. No.: US 2022/0140420 A1
(43) Pub. Date: May 5, 2022

(54) COOLANT SUPPLYING MODULE

(71) Applicants: HYUNDAI MOTOR COMPANY, Seoul (KR); KIA CORPORATION, Seoul (KR)

(72) Inventors: Yeonho Kim, Seoul (KR); Jae Yeon Kim, Hwaseong-si (KR); Jeawan Kim, Gwangmyeong-si (KR); Yu Man Won, Suwon-si (KR); Yong Hoe Jeong, Seoul (KR); Dong June Kang, Incheon (KR)

(21) Appl. No.: 17/223,247

(22) Filed: Apr. 6, 2021

(30) Foreign Application Priority Data
Nov. 5, 2020 (KR) 10-2020-0146708

(51) Int. Cl. H01M 10/667; H01M 10/613; H01M 10/625; H01M 10/63; H01M 10/6568; H05K 7/20

(52) U.S. Cl. CPC H01M 10/667; H01M 10/613; H01M 10/625; H01M 2220/20; H01M 10/6568; H05K 7/20272; H01M 10/63

(57) ABSTRACT

A coolant supplying module is for supplying a coolant stored in a shared reservoir tank to an electrical component cooling circuit and a battery cooling circuit, and includes a main body connected to the shared reservoir tank, at least one valve mounting portion formed inside the main body to mount at least one valve device, at least one pump mounting portion formed inside the main body to mount at least one water pump, and a control portion mounted outside the main body and electrically connected to the at least one valve device and the at least one water pump.

### CROSS REFERENCE TO RELATED APPLICATIONS

This application claims priority to and the benefit of Korean Patent Application No. 10-2020-0146708 filed in the Korean Intellectual Property Office on Nov. 5, 2020, the entire contents of which are incorporated herein by reference.

### BACKGROUND

### (a) Field

The present disclosure relates to a coolant supplying module. More specifically, the present disclosure relates to a coolant supply module capable of smoothly supplying coolant to electrical component and a battery module, and to install various components.

### (b) Description of the Related Art

Nowadays, while interest in energy efficiency and an environment pollution problem increases, development of an environmentally-friendly vehicle that can substantially replace an internal combustion engine vehicle is requested. The environmentally-friendly vehicle is classified into an electric vehicle that is driven using a fuel cell or electricity as a power source and a hybrid vehicle that is driven using an engine and an electric battery.

Here, an electric vehicle that uses a fuel cell converts chemical reaction energy of oxygen and hydrogen to electrical energy to occur a driving torque, and in this process, thermal energy occurs by a chemical reaction within the fuel cell and it is essential in securing a performance of the fuel cell to effectively remove a generated heat.

Further, a hybrid vehicle generates a driving torque by driving a motor using electricity that is supplied from an electric battery or the fuel cell together with an engine operating with general fuel, and when effectively removing a heat occurring in a fuel cell, a battery, and a motor, a performance of the motor may be secured.

Such a hybrid vehicle is driven in an EV mode that is driven by a motor upon constant speed driving, gentle driving, and low and medium constant speed driving, upon acceleration and rapid acceleration, an internal combustion engine and a motor are simultaneously driven, and upon high constant speed driving, a motor is stopped and the hybrid vehicle is operated by the internal combustion engine.

Accordingly, in a hybrid vehicle, an engine cooling circuit for circulating and cooling coolant in an engine and an electrical component cooling circuit for circulating and cooling coolant in an electric power component including a motor are each provided.

Meanwhile, an electric vehicle is provided with an electric component cooling circuit and a battery cooling circuit for cooling by circulating coolant to the electric component and the battery.

However, in such a conventional electric vehicle, as an electric component cooling circuit and a battery cooling circuit are each configured with a separate close and seal circuit. Accordingly, as two reservoir tanks used to each cooling circuit must be provided, they are difficult to be mounted in a narrow engine compartment, and a manufacturing cost is increased due to the increasing of the constituent elements.

Also, the weight is increased due to the increasing of the constituent elements and productivity may be deteriorated by the increasing of a mounting time of each reservoir tank.

In addition, when a water pump provided in each circuit is mounted, layout restrictions may occur due to a narrow space.

The above information disclosed in this Background section is only for enhancement of understanding of the background of the disclosure, and therefore it may contain information that does not form the prior art that is already known in this country to a person of ordinary skill in the art.

### SUMMARY

The present disclosure has been made in an effort to provide a coolant supplying module having advantages of supplying a coolant from a shared reservoir tank to both an electrical component cooling circuit and a battery cooling circuit, and a convenient connection of various parts and piping.

A coolant supplying module according to an exemplary embodiment of the present disclosure is for supplying a coolant stored in a shared reservoir tank to an electrical component cooling circuit and a battery cooling circuit, and includes a main body connected to the shared reservoir tank, at least one valve mounting portion formed inside the main body to mount at least one valve device, at least one pump mounting portion formed inside the main body to mount at least one water pump, and a control portion mounted outside the main body and electrically connected to the at least one valve device and the at least one water pump.

The main body may further include a tank connecting portion provided at an upper end of the main body to be connected to the reservoir tank and communicating with an inside of the main body.

A connection aperture may be formed at the reservoir tank corresponding to the tank connecting portion.

A seal ring may be installed between the connection aperture and the tank connecting portion to prevent the coolant stored in the reservoir tank from leaking to an outside of the main body.

The at least one valve mounting portion may be located above the main body.

The at least one pump mounting portion may include a first pump mounting portion provided on a first side of the lower portion based on the at least one valve mounting portion provided inside the main body, and a second pump mounting portion provided on a second side of the lower portion based on the at least one valve mounting portion provided inside the main body.

A first port may be integrally formed on the first pump mounting portion, and the second port may be integrally formed on the second pump mounting portion.

A first water pump provided on the electrical component cooling circuit may be mounted on the first pump mounting portion.

A second water pump provided on the battery cooling circuit may be mounted on the second pump mounting portion.

The first pump mounting portion may be disposed at a position opposite to the second pump mounting portion, and may be located on a same line at both lower sides of the main body.

Each drive shaft of the at least one valve device and the at least one water pump may be disposed parallel to each other.

The control portion may include a case mounted on an outside of the main body; and a printed circuit board (PCB) provided inside the case and electrically connected to control operations of the at least one valve device and the at least one water pump.

A connector connecting portion may be formed at the case to selectively apply a control signal to the printed circuit board (PCB).

The main body may further include a component connecting portion to which a chiller, or a water-cooled condenser, or a heat exchanger in connected.

The at least one water pump may be connected to the electrical component cooling circuit or the battery cooling circuit.

The at least one valve device may change a flow path of the coolant circulating each of the electrical component cooling circuit and the battery cooling circuit.

According to a coolant supplying module according to an exemplary embodiment, since the coolant is supplied from the shared reservoir tank to both the electrical component cooling circuit and the battery cooling circuit and various constituent elements are easily mounted, spatial utility of a narrow space may be improved.

In addition, an exemplary coolant supplying module integrates water pumps for supplying coolant to each circuit and a valve for selectively supplying coolant to each circuit connected to the water pump, thereby reducing number of parts and improving package properties.

In addition, an exemplary coolant supplying module may simplify the layout of the connection pipes, and may be possible to improve the mountability and maintainability.

Furthermore, required number of separate parts realizing the layout of the connection pipes may be minimized, thereby decreasing weight and cost, and improving productivity by reducing required assembly processes.

### BRIEF DESCRIPTION OF THE FIGURES

FIG. 1 is a perspective view of a coolant supplying module according to an exemplary embodiment.

FIG. 2 is an exploded perspective view of a coolant supplying module according to an exemplary embodiment.

FIG. 3 is a perspective rear view of a reservoir tank mounted to a coolant supplying module according to an exemplary embodiment.

FIG. 4 is a partial cross-section view of a state in which a coolant supplying module and a reservoir tank are connected according to an exemplary embodiment.

### DETAILED DESCRIPTION

An exemplary embodiment of the present disclosure will hereinafter be described in detail with reference to the accompanying drawings.

Exemplary embodiments disclosed in the present specification and the constructions depicted in the drawings are only the preferred embodiments of the present disclosure, and do not cover the entire scope of the present disclosure. Therefore, it will be understood that there may be various equivalents and variations at the time of the application of this specification.

In order to clarify the present disclosure, parts that are not connected to the description will be omitted, and the same elements or equivalents are referred to with the same reference numerals throughout the specification.

Also, the size and thickness of each element are arbitrarily shown in the drawings, but the present disclosure is not necessarily limited thereto, and in the drawings, the thickness of layers, films, panels, regions, etc., are exaggerated for clarity.

In addition, unless explicitly described to the contrary, the word “comprise” and variations such as “comprises” or “comprising”, will be understood to imply the inclusion of stated elements but not the exclusion of any other elements.

Furthermore, each of terms, such as “ . . . unit”, “ . . . means”, “ . . . part”, and “ . . . member” described in the specification, mean a unit of a comprehensive element that performs at least one function or operation.

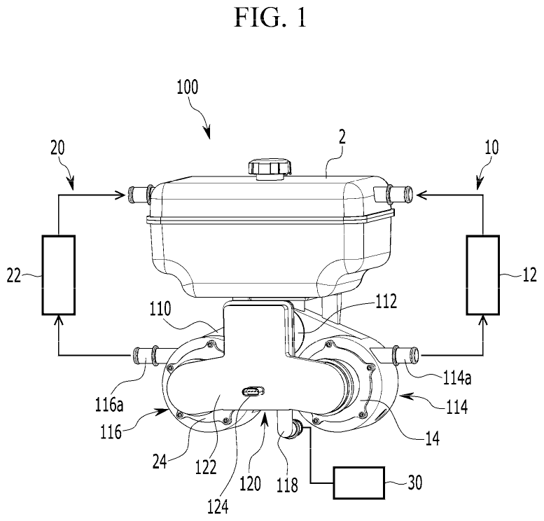

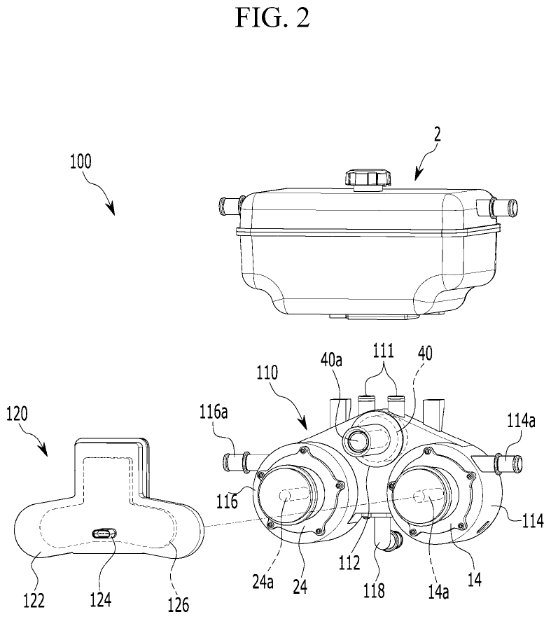

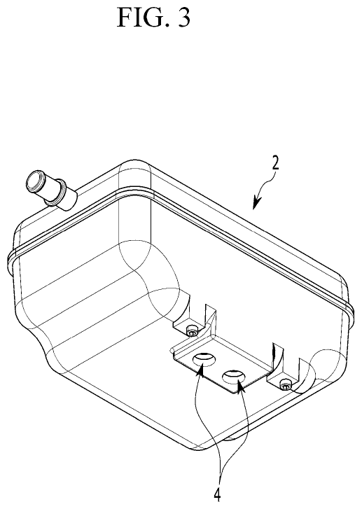

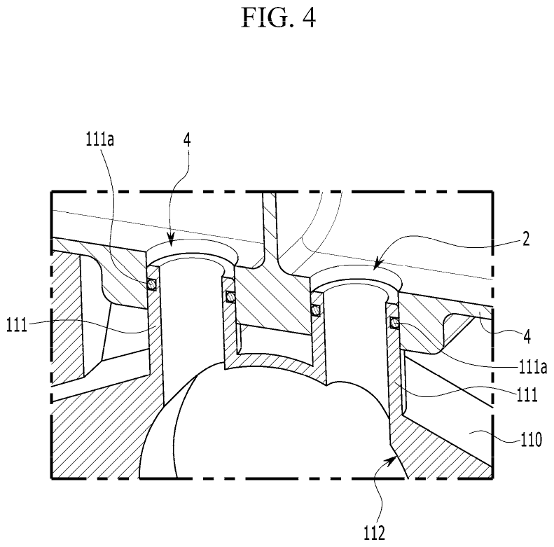

FIG. 1 is a perspective view of a coolant supplying module according to an exemplary embodiment, FIG. 2 is an exploded perspective view of a coolant supplying module according to an exemplary embodiment, FIG. 3 is a perspective rear view of a reservoir tank mounted to a coolant supplying module according to an exemplary embodiment, and FIG. 4 is a partial cross-section view of a state in which a coolant supplying module and a reservoir tank are connected according to an exemplary embodiment.

Referring to the drawings, a coolant supplying module 100 according to an exemplary embodiment may supply, a coolant stored in a shared reservoir tank 2 to an electrical component cooling circuit 10 for supplying a coolant to an electrical component 12, and the coolant to a battery cooling circuit 20 for supplying the coolant to a battery 22.

That is, the coolant supplying module 100 may supply the coolant stored in the shared reservoir tank 2 to both of the electrical component cooling circuit 10 and the battery cooling circuit 20.

As shown in FIG. 1 to FIG. 4, such a coolant supplying module 100 includes a main body 110, at least one valve mounting portion 112, at least one pump mounting portion 113, and control portion 120.

Herein, the at least one water pump mounting portion 112 and the pump mounting portion 113 may be integrally formed in the main body 110.

In the present exemplary embodiment, the main body 110 is connected to the shared reservoir tank 2 disposed at the top surface. A space (not shown) may be formed inside the main body 110 so that a coolant receives.

In addition, the main body 110 may further include a tank connecting portion 111 provided at an upper end of the main body 110 to be connected to the shared reservoir tank 2, as shown in FIG. 2 and FIG. 4.

Meanwhile, connecting aperture 4 may be formed in a lower portion of the shared reservoir tank 2 in corresponding to the tank connecting portion 111.

That is, the tank connecting portion 111 is inserted into the connecting aperture 4 formed in the shared reservoir tank 2 to interconnect the shared reservoir tank 2 and the main body 110.

A seal ring 111a may be installed between the connection aperture 4 and the tank connecting portion 111 to prevent the coolant stored in the shared reservoir tank 2 from leaking to an outside of the main body 110.

That is, the seal ring 111a seals between an interior circumference of the connecting aperture 4 and an exterior circumference of the tank connecting portion 111. Accordingly, the seal ring 111a may prevent the coolant from leaking to the outside of the main body 110 along the exterior circumference of the tank connecting portion 111.

In the present exemplary embodiment, the valve mounting portion 112 is formed inside of the main body 110. The valve mounting portion 112 may be located above the main body 110.

The valve device 40 may change a flow path of the coolant circulating each of the electrical component cooling circuit 10 and the battery cooling circuit 20.

The at least one pump mounting portion 113 may be formed inside the main body 110 such that first and second water pumps 14 and 16 included in the electrical component cooling circuit 10 and the battery cooling circuit 20 may be mounted.

The at least one pump mounting portion 113 may include a first and second pump mounting portion 114 and 116.

First, in the first pump mounting portion 114, the first water pump 14 provided on the electrical component cooling circuit 10 is mounted.

Herein, the first pump mounting portion 114 may be provided on a first side of the lower portion based on the valve mounting portion 112 provided inside an upper portion of the main body 110.

In the second pump mounting portion 116, the second water pump 24 provided on the battery cooling circuit 20 is mounted.

The second pump mounting portion 116 may be provided on a second side of the lower portion based on the valve mounting portion 112 provided inside a upper portion of the main body 110.

The first pump mounting portion 114 may be disposed at a position opposite to the second pump mounting portion 116, and may be located on a same line at both lower sides of the main body 110.

Meanwhile, the first pump mounting portion 114 may be integrally formed with a first port 114a protruding to the outside of the main body 110 in a direction opposite to the second pump mounting portion 116.

In addition, the second pump mounting portion 116 may be integrally formed with a second port 116a protruding to the outside of the main body 110 in a direction opposite to the first pump mounting portion 114.

The first port 114a may be connected to the electrical component cooling circuit 10 through a connection pipe, and the second port 116a may be connected to the battery cooling circuit 20 through the connection pipe.

Meanwhile, in the present exemplary embodiment, the main body 110 may further include a component connecting portion 118 to which a chiller, or a water-cooled condenser, or a heat exchanger in connected.

The component connection part 118 may be located between the first pump mounting portion 114 and the second pump mounting portion 116 in a lower portion of the main body 110.

The control portion 120 is mounted outside the main body 110. Based on the drawing, the control unit 120 may be mounted on the front or rear surfaces of the main body 110 corresponding to the first and second water pumps 14 and 24 mounted on the main body 110, and the valve device 40.

Herein, the control portion 120 may include a case 122 and a printed circuit board (PCB) 126.

First, the case 122 may be mounted on an outside of the front and rear surface of the main body 110 based on the drawing.

The PCB 126 is provided inside the case 122. Herein, the PCB 126 may be electrically connected to the first and second water pumps 14 and 24 and the valve device 40 so as to control operations of the first and second water pumps 14 and 24 and the valve device 40.

Meanwhile, a connector connecting portion 124 may be formed at the case 120 to selectively apply a control signal to the PCB 126.

The connector connecting portion 124 may be connected to a wire or cable connected to a controller provided in the vehicle.

The control portion 120 configured as described above may disposed perpendicular to each of a drive shafts 14a, 24a, and 40a provided in the first and second water pumps 14 and 24 and the valve device 40.

Herein, based on the drawing, the drive shafts 14a and 24a of the first and second water pump 14 and 24, and the drive shaft 40a of the valve device 40 may be disposed parallel to each other toward the front and rear directions of the main body 110.

Accordingly, the control portion 120 may be mounted to the main body 110 which is mounted to the first and second water pumps 14 and 24 and the valve device 40 through a single assembly process.

The coolant supplying module 100 configured as described above is configured by mounting the first and second water pumps 14 and 24 and the valve device 40 inside the main body 110, and directly mounting the control portion 120 to the outside, thereby minimizing the use of separate connection piping and connection wiring.

In addition, it is possible to minimize the use of a mounting bracket for mounting the shared reservoir tank 2 and the main body 110 to the vehicle.

Furthermore, the first and second water pumps 14 and 24 may be positioned under the main body 110 to form a center of gravity of the main body 110 under the main body 110 to stabilize the center of gravity of the cooling water supply module 110. For this reason, running stability and durability performance can be advantageous.

In addition, the operator may stably fasten the coolant supplying module 100 in a state in which the shared reservoir tank 2 is assembled to the vehicle.

As described above, according to a coolant supplying module 100 according to an exemplary embodiment, depending on whether the electrical component 12 and the battery 22 is to be separately cooled or integrally cooled, e.g., according to a driving mode of a vehicle, the electrical component cooling circuit 10 and the battery cooling circuit 20 may be selectively connected or separated in circulating the coolant through the operation control of the first and second water pump 12 and 24 and the valve device 40.

In addition, a single reservoir tank 2 may be shared by the electrical component cooling circuit 10 and the battery cooling circuit 20.

According to a coolant supplying module 100 according to an exemplary embodiment, since the coolant is supplied from the shared reservoir tank 2 to both the electrical component cooling circuit 10 and the battery cooling circuit 20 and various constituent elements are easily mounted, spatial utility of an engine compartment may be improved.

The exemplary coolant supplying module may directly mount the first and second water pumps 14 and 24 for supplying the coolant to the electrical component cooling circuit 10 and the battery cooling circuit 20 and may be efficiently connected with connection pipes. Therefore, a layout of connection pipes may be simplified, and mountability and maintainability may be improved.

In addition, according to the present disclosure, by applying a structure in which the control portion 120 is directly fastened to the main body 110, thereby achieving modularization, reducing the overall size, and minimizing connection wiring.

Furthermore, required number of separate parts realizing the layout of the connection pipes may be minimized, thereby decreasing weight and cost, and improving productivity by reducing required assembly processes.

While this disclosure has been described in connection with what is presently considered to be practical example embodiments, it is to be understood that the disclosure is not limited to the disclosed embodiments. On the contrary, it is intended to cover various modifications and equivalent arrangements included within the spirit and scope of the appended claims.

1. A coolant supplying module for supplying a coolant stored in a shared reservoir tank to an electrical component cooling circuit and a battery cooling circuit, comprising:
a main body connected to the shared reservoir tank;
at least one valve mounting portion formed inside the main body configured to mount at least one valve device;
at least one pump mounting portion formed inside the main body configured to mount at least one water pump; and
a control portion mounted outside the main body and electrically connected to the at least one valve device and the at least one water pump.

2. The coolant supplying module of claim 1, wherein the main body further includes a tank connecting portion provided at an upper end of the main body configured to be connected to the reservoir tank and communicating with an inside of the main body.

3. The coolant supplying module of claim 2, wherein a connection aperture is formed at the reservoir tank corresponding to the tank connecting portion.

4. The coolant supplying module of claim 3, wherein a seal ring is installed between the connection aperture and the tank connecting portion, the seal ring being configured to prevent the coolant stored in the reservoir tank from leaking to an outside of the main body.

5. The coolant supplying module of claim 1, wherein the at least one valve mounting portion is located above the main body.

6. The coolant supplying module of claim 1, wherein the at least one pump mounting portion includes:
a first pump mounting portion provided on a first side of the lower portion based on the at least one valve mounting portion provided inside the main body; and
a second pump mounting portion provided on a second side of the lower portion based on the at least one valve mounting portion provided inside the main body.

7. The coolant supplying module of claim 6, wherein a first port is integrally formed on the first pump mounting portion, and a second port is integrally formed on the second pump mounting portion.

8. The coolant supplying module of claim 6, wherein the first pump mounting portion includes a first water pump provided on the electrical component cooling circuit.

9. The coolant supplying module of claim 6, wherein The second pump mounting portion includes a second water pump provided on the battery cooling circuit.

10. The coolant supplying module of claim 6, wherein the first pump mounting portion is disposed at a position opposite to the second pump mounting portion, and is located on a same line at both lower sides of the main body.

11. The coolant supplying module of claim 1, wherein each drive shaft of the at least one valve device and the at least one water pump are disposed parallel to each other.

12. The coolant supplying module of claim 1, wherein the control portion includes:
a case mounted on an outside of the main body; and
a printed circuit board (PCB) provided inside the case and electrically connected to control operations of the at least one valve device and the at least one water pump.

13. The coolant supplying module of claim 12, wherein a connector connecting portion may be formed at the case to selectively apply a control signal to the printed circuit board.

14. The coolant supplying module of claim 1, wherein the main body further includes a component connecting portion to which a chiller, a water-cooled condenser, or a heat exchanger in connected.

15. The coolant supplying module of claim 1, wherein the at least one water pump is connected to the electrical component cooling circuit or the battery cooling circuit.

16. The coolant supplying module of claim 1, wherein the at least one valve device changes a flow path of the coolant circulating each of the electrical component cooling circuit and the battery cooling circuit.
